(19) United States
(12) Patent Application Publication
(10) Pub. No.: US 2026/0328845 A1
(43) Pub. Date: Oct. 22, 2026

(54) MONITORING APPARATUS FOR A PROTECTION DEVICE

(71) Applicant: Eaton Intelligent Power Limited, Dublin (IE)

(72) Inventors: Arun Prasad, Pune (IN); Prashant Zatale, Pune (IN); Travis Spoone, Greenwood, SC (US); Bhushan Kadu, Pune (IN); Swaminath Katte, Pune (IN)

(21) Appl. No.: 19/567,829

(22) Filed: Mar. 16, 2026

(30) Foreign Application Priority Data
Mar. 21, 2025 (IN) 202511025967

(51) Int. Cl. G01R 31/327; G01R 15/22; G01R 19/145; G01R 19/165; H02H 7/22

(52) U.S. Cl. CPC G01R 31/327; G01R 15/22; G01R 19/145; G01R 19/16571; H02H 7/226

(57) ABSTRACT

A monitoring apparatus includes: a base configured to attach to an exterior of a cable protection device, the cable protection device including a current path that opens in response to an electrical fault; and a fault detection system in the base, the fault detection system including: a fault indication module configured to produce a fault indication when the current path is open. The base is configured to fit over at least a portion of the exterior of any one of a plurality of cable protection devices, and at least two of the plurality of cable protection devices have different characteristics.

### CROSS-REFERENCE TO RELATED APPLICATION

This application claims priority to Indian Patent Application No. 202511025967, filed Mar. 21, 2025 and titled MONITORING APPARATUS FOR A PROTECTION DEVICE, which is incorporated herein by reference in its entirety.

### TECHNICAL FIELD

This disclosure relates to a monitoring apparatus for a protection device.

### BACKGROUND

A protection device (such as a cable limiter) protects items in an electrical power system from fault conditions such as, for example, overcurrent, short circuit, and overvoltage faults.

### SUMMARY

In one aspect, a monitoring apparatus includes: a base configured to attach to an exterior of a cable protection device, the cable protection device including a current path that opens in response to an electrical fault; and a fault detection system in the base, the fault detection system including: a fault indication module configured to produce a fault indication when the current path is open. The base is configured to fit over at least a portion of the exterior of any one of a plurality of cable protection devices, and at least two of the plurality of cable protection devices have different characteristics.

Implementations may include one or more of the following features.

The fault detection system also may include an electrical sensor configured to measure one or more properties of electricity in the current path and to produce an output based on the one or more properties of electricity in the current path, and the fault indication module may be configured to produce the fault indication when the output indicates that the current path is open. The monitoring apparatus also may include: a first electrical connection configured to electrically connect to the current path; a second electrical connection configured to electrically connect to the current path; and the electrical sensor may include a voltage sensor electrically connected to the first electrical connection and the second electrical connection, the voltage sensor configured to measure a potential difference between the first and second electrical connections and to produce an output that represents the potential difference; and the fault detection system may be configured to produce the fault indication when there is a non-zero potential difference. The voltage sensor may include an optical sensor that emits light when there is a non-zero potential difference; and the fault detection system also may include: a detector configured to detect light and produce an electrical signal based on detected light; and an electronic control system configured to produce the fault indication based on the electrical signal. The monitoring apparatus also may include: a modulation module electrically connected to the electronic control system and the current path; and a demodulation module electrically connected to the electronic control system and the current path. The modulation module may be configured to modulate electrical current in the current path to produce modulated electrical current based on a unique identifier associated with the electronic control system; and the demodulation module may be configured to demodulate the modulated electrical current. The fault detection system may include a current sensor configured to sense current in the current path and to produce a measurement of an amount of current in the current path; and the fault detection system may be configured to produce the fault indication when the measurement indicates that the amount of current flowing in the current path is below a threshold.

The fault detection system may include: an electronic control system; a modulation module electrically connected to the current path and the electronic control system; and a demodulation module electrically connected to the current path and the electronic control system, and the modulation module may be configured to modulate electrical current on the current path based on a unique identifier associated with the electronic control system to produce a modulated signal; and the demodulation module may be configured to demodulate the modulated signal to produce a demodulated signal; and the electronic control system may produce the fault indication when the demodulated signal is not received at the electronic control system.

The monitoring apparatus also may include a communications device configured to provide the fault indication to a separate device. The communications device may include a wireless communication device.

The base may include a flexible attachment device that extends from the base and fits over at least a portion of the exterior of the cable protection device to attach the base to the exterior of the cable protection device.

The characteristics may include one or more of an outer diameter, a cable size, a length, a terminal type, and an electrical rating.

The characteristics may include a spatial feature of an exterior of the cable protection device.

In another aspect, a cable protection monitoring system is configured to: present a visual representation of a fleet of fault detection apparatuses, where each of the fault detection apparatuses is attached to a respective one of a plurality of cable protection devices, and each of the fault detection apparatuses is configured to produce a fault indication signal in response to detecting a fault in its respective attached cable protection device. The cable protection monitoring system is also configured to receive a fault indication signal for one or more of the fault detection apparatuses; and display a fault symbol in association with the one or more of the fault detection apparatuses in the visual representation of the fleet.

Implementations may include one or more of the following features.

Each fault detection apparatus may be associated with a unique identifier, and the fault indication signal produced by each fault detection apparatus may include a representation of the unique identifier.

The cable protection monitoring system also may include the fleet of fault detection apparatuses.

In another aspect, a system includes: a base configured for mounting to an exterior of a cable protection device; a fault detection system in the base, the fault detection system including: a sensor configured to detect a fault in the cable protection device and to present a visible indication of a detected fault in the cable protection device; and an interface configured to trigger a status check to determine whether a fault is present in the cable protection device.

The sensor may include an optical sensor electrically connected to two points along a current path in the cable protection device, and the optical sensor may be configured to emit light in response to a non-zero potential difference between the two points.

Implementations of any of the techniques described herein may include a system, an assembly, a cable protection monitoring system, a detection system, fault detection system, machine-executable instructions, and/or a method. The details of one or more implementations are set forth in the accompanying drawings and the description below. Other features will be apparent from the description and drawings, and from the claims.

### DRAWING DESCRIPTION

FIG. 1 is a block diagram of an electrical power system that includes a protection device.

FIG. 2 is an end view of a fleet of protection devices.

FIG. 3 is a side cross-sectional view of an example of a monitoring apparatus attached to an exterior of the protection device of FIG. 1.

FIG. 4 is a side cross-sectional view of another monitoring apparatus attached to the exterior of the protection device of FIG. 1.

FIG. 5 is a block diagram of a detection system.

FIGS. 6A and 6B are block diagrams of another monitoring apparatus.

FIG. 6C shows a sensor that includes a light-emitting diode.

FIGS. 7A and 7B are block diagrams of another monitoring apparatus.

FIG. 8 is a perspective exterior view of a system that includes a monitoring apparatus mounted to an exterior of another protection device.

FIG. 9A is a perspective view of the monitoring apparatus of FIG. 8.

FIG. 9B is an end view of the monitoring apparatus of FIG. 8.

FIG. 9C is a top view of the monitoring apparatus of FIG. 8.

FIG. 10 is a flow chart of an example of a process for producing a fault indication with a monitoring apparatus that is attached to a protection device.

FIG. 11 shows a system that includes a fleet and a remote station.

### DETAILED DESCRIPTION

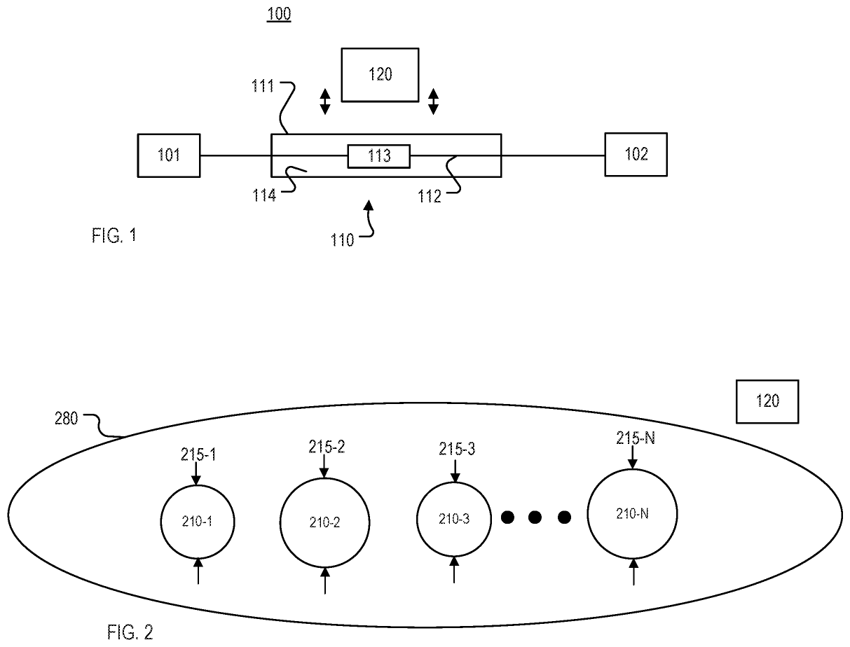

FIG. 1 is a block diagram of an electrical power system 100. The electrical power system includes a protection device 110 and a monitoring apparatus 120 that can be mounted to an exterior 111 of a housing 114 of the protection device 110. The protection device 110 protects one or more components in the power system 100 from electrical faults. The protection device may be, for example, a cable limiter, an electrical cable protection device, and/or an overcurrent protection device. The overcurrent protection device may be a non-indicative type overcurrent protection device, which is a device that protects electrical circuits from excessive current without providing a perceivable (for example, visual or audible) status indication. Examples of non-indicative type overcurrent protection devices include, without limitation, cable limiters, high-voltage fuses, and medium-voltage fuses. The monitoring apparatus 120 monitors the protection device 110 and provides a perceivable indication in response to a fault condition in the protection device 110. The perceivable indication may be, for example, emitted light or an electrical signal that is transmitted to a separate device.

The monitoring apparatus 120 can be attached to and removed from the exterior 111 of the housing 114 without damaging the housing 114 or the monitoring apparatus 120. For example, the monitoring apparatus 120 may have flexible arms or sides that deform outward as the monitoring apparatus 120 is pressed onto the exterior 111 and deform inward to secure the monitoring apparatus 120 to the exterior 111.

Moreover, in some implementations, the protection device 110 can be attached to the exterior of any one of a plurality of non-identical protection devices. FIG. 2 is an end view of a fleet 280 of protection devices. The fleet 280 includes N protection devices 210-1 to 210-N, where N is a positive integer that is greater than two. Each protection device 210-1 to 210-N has respective characteristics such as, for example, an outer diameter, length, cable size, terminal types, voltage rating, and current rating. In FIG. 2, each of the N protection devices 210-1 to 210-N has a respective outer diameter 215-1 to 215-N, and at least one of the outer diameters 215-1 to 215-N is different from the other outer diameters. The monitoring apparatus 120 can be attached to the exterior of any one of the protection devices 210-1 to 210-N even though the outer diameters 215-1 to 215-N (and other characterizes) are not the same.

The monitoring apparatus 120 may be attached to a protection device at the point of manufacture or assembly and provided to an end user or distributor as an assembled system that includes the protection device 110 and the monitoring apparatus 120, the monitoring apparatus 120 may be packaged as a stand-alone item for retrofitting an existing protection device, and/or the protection device 110 and the monitoring apparatus 120 may be packaged as an unassembled kit.

Before discussing examples of the monitoring apparatus 120, an overview of the system 100 is provided. The protection device 110 includes an electrical current path 112 that passes through the housing 114. The current path 112 is any electrical conductor and may be, for example, a wire or electrical cable. The electrical current path 112 includes an opening element 113 that opens the electrical current path 112 in response to an overcurrent condition. For example, the opening element 113 may be a fuse or a switch. When the opening element 113 is closed, the current path 112 electrically connects a source system 101 to a load system 102. When the opening element 113 is opened or severed, the source system 101 and the load system 102 are electrically disconnected from each other.

The source system 101 includes one or more sources of alternating current (AC) electricity. For example, the source system 101 may include a generator, an AC power grid, a substation, a DC-to-AC power converter, an AC-to-AC power converter, a transformer, and/or a distributed energy resource (DER). The load system 102 includes one or more loads that consume, absorb, and/or transfer electricity. The load system 102 may include, for example, a motor, a lighting system, a transformer, a voltage regulator, an AC-to-DC converter, or an AC-to-AC converter. Furthermore, the source system 101 also may receive and utilize AC power and the load system 102 may generate AC power. In other words, in some implementations, electrical power may flow in two directions in the protection device 110.

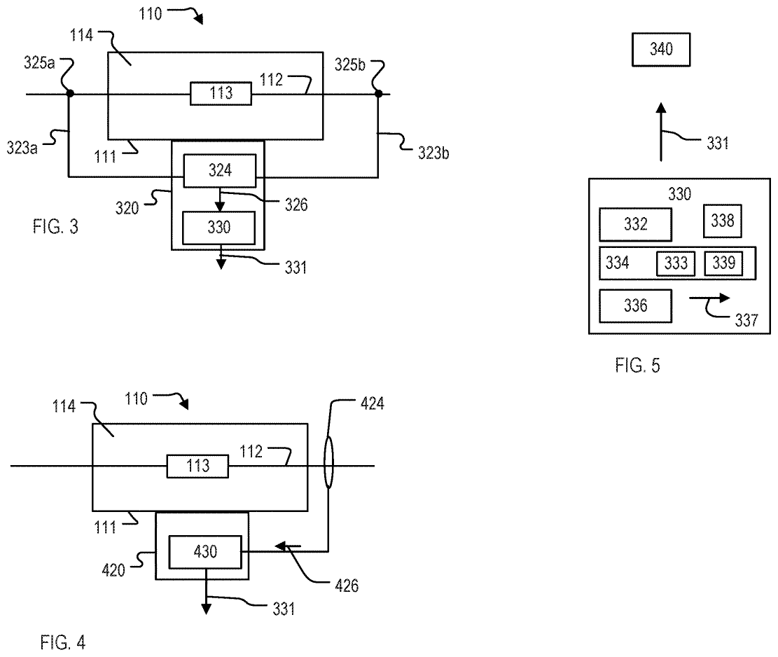

FIG. 3 is a side cross-sectional view of a monitoring apparatus 320 attached to the exterior 111 of the protection device 110. The monitoring apparatus 320 is an example of the monitoring apparatus 120. The monitoring apparatus 320 can be removed from the exterior 111 and reattached to the exterior 111 or attached to another protection device 110 repeatedly and without damaging the monitoring apparatus 320 or the protection device 110. The monitoring apparatus 320 includes an electrical sensor 324 that measures one or more properties of electricity that flows in the current path 112. The electrical sensor 324 is electrically connected to a first electrical connection 323a and a second electrical connection 323b. Each of the electrical connections 323a and 323b is electrically connected to a respective point 325a and 325b on the current path 112. The point 325a is on a first side of the protection device 110 and the point 325b is on a second side of the protection device 110.

When the opening element 113 is closed, electrical current can flow in the current path 112 and the points 325a and 325b are at the same potential. When the opening element 113 is opened, current cannot flow in the current path 112, there a non-zero voltage potential difference between the points 325a and 325b. Thus, the voltage between the points 325a and 325b may be used to monitor the state of the current path 112.

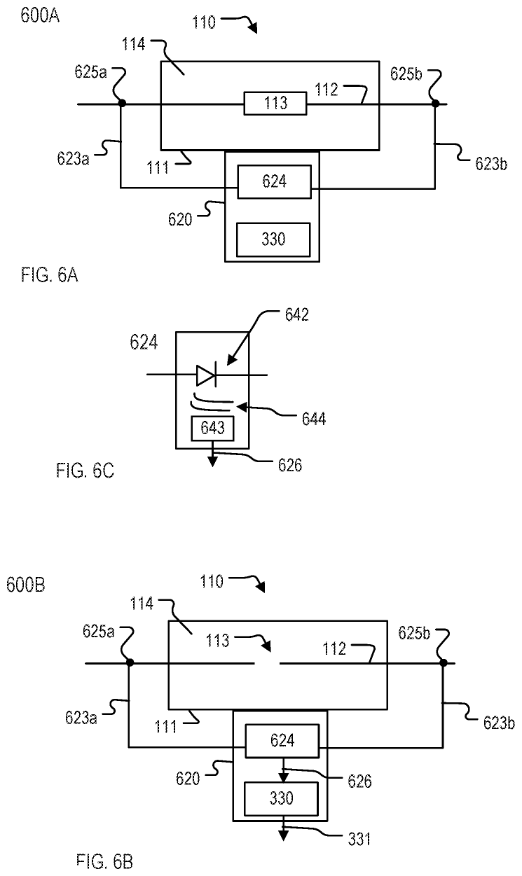

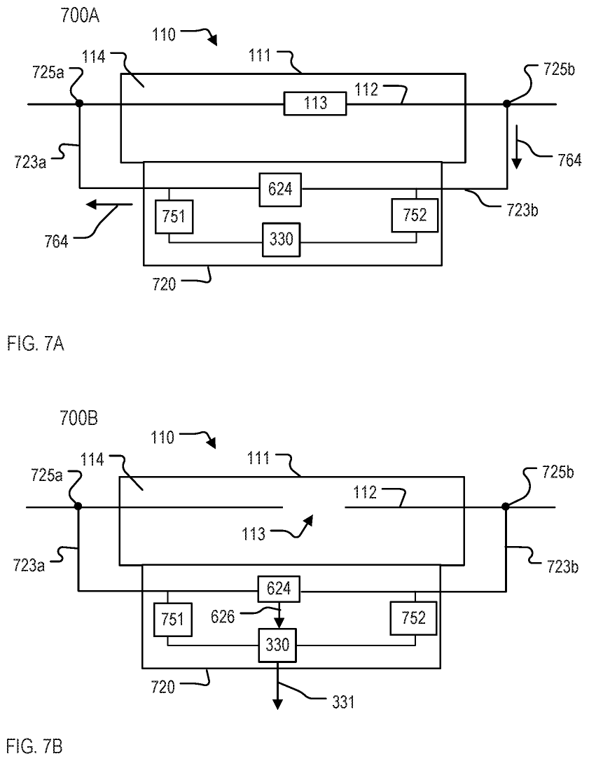

The electrical sensor 324 is any sensor that produces an output 326 based on the voltage between the points 325a and 325b. For example, the electrical sensor 324 may be a light-emitting diode (LED) through which current flows when the voltage across the LED exceeds a threshold determined by the materials and structure of the LED. In this example, when the current path 112 is closed, there is substantially no voltage across the LED, the LED does not emit light, and there is no output 326. When the current path 112 opens, the voltage across the LED increases such that current can flow through the LED. The LED emits light as the output 326. The output 326 is detected by the detection system 330, which produces a fault indication 331 in response to detecting the output 326. The detection system 330 does not produce the fault indication 331 when the LED does not emit light. FIGS. 6A, 6B, 7A, and 7B show examples of a sensor that includes a light-emitting diode.

Other implementations are possible. For example, the electrical sensor 324 may be a semiconductor diode that conducts current only when there is a non-zero voltage difference between the points 325a and 325b. In this example, the output 326 is a current measurement and the detection system 330 produces the fault indication 331 only when current flows through the diode. In another example, the electrical sensor 324 a voltage sensor that provides indication of the voltage between the points 325a and 325b as the output 326. In this implementation, the detection system 330 receives the output 326 and determines whether to produce the fault indication 331 based on the measured voltage between the points 325a and 325b.

Furthermore, in some implementations, a current sensor is used to monitor the status of the current path 112. FIG. 4 is a side cross-sectional view of a monitoring apparatus 420 attached to the exterior 111 of the protection device 110. The monitoring apparatus 420 is another example of the monitoring apparatus 120. The monitoring apparatus 420 is similar to the monitoring apparatus 320, except the monitoring apparatus 420 includes a detection system 430 that receives an output 426 from a current sensor 424. The current sensor 424 is positioned relative to the current path 112 and produces the output 426, which is a representation of the amount of current flowing in the current path 112. The current sensor 424 may be, for example, a Rogowski coil or a current transformer (CT). The detection system 430 determines whether to produce the fault indication 331 based on the output 426.

FIG. 5 is a block diagram of the detection system 330. The detection system 330 includes an electronic processing module 332, an electronic storage 334, and an input/output (I/O) interface 336. The detection system 330 also includes a power source 338 that provides power to the various components of the detection system 330. The power source 338 may be, for example, a battery.

The electronic processing module 332 includes one or more electronic processors. The electronic processors of the module 332 may be any type of electronic processor and may or may not include a general-purpose central processing unit (CPU), a graphics processing unit (GPU), a microcontroller, a field-programmable gate array (FPGA), Complex Programmable Logic Device (CPLD), and/or an application-specific integrated circuit (ASIC). The detection system 330 may include a microcontroller.

The electronic storage 334 may be any type of electronic memory that is capable of storing data, and the electronic storage 334 may include volatile and/or non-volatile components. The electronic storage 334 and the processing module 332 are coupled such that the processing module 332 may access or read data from the electronic storage 334 and may write data to the electronic storage 334. The electronic storage 334 also may store data received from the electrical sensor 324. For example, the electronic storage 334 may store the output 326 or the output 426 over time. In another example, the electronic storage 334 also may store instructions as, for example, a computer program or function, that when executed by the electronic processing module 332, analyzes data from the electrical sensor 324 to determine whether or not a fault condition is present. For example, the electronic storage 334 may store a threshold voltage value used to determine when the points 325a and 325b are electrically disconnected.

Additionally, the electronic storage 334 may store instructions for generating the fault indication 331. For example, the electronic storage 334 may generate the fault indication 331 only when the output 326 shows that the current path 112 is open. In some implementations, the fault indication 331 is produced periodically regardless of whether or not the current path 112 is open but includes additional information about the current path 112. For example, the fault indication 331 may include a binary flag that has a first value when the current path 112 is open and a second value when the current path 112 is closed.

Furthermore, the electronic storage 334 also may store information to uniquely identify the detection system 330 and/or a monitoring apparatus that includes the detection system 330. For example, the electronic storage 334 may include an identifier 339 that uniquely identifies the detection system 330. The identifier 339 may be, for example, an alphanumeric value is that is unique to the detection system 330 and distinguishes the detection system 330 from other instances of the detection system. Additionally, the electronic storage 334 may include a fault record 333 that stores historical information about fault conditions detected by the detection system and/or historical measurements from the electrical sensor 324.

The I/O interface 336 is any interface that allows the fault indication 331 to be provided to a remote device 340. For example, the I/O interface 336 may include, a serial or parallel port, a Universal Serial Bus (USB) connection, and/or any type of network interface, such as, for example, Ethernet. The I/O interface 336 also may allow communication without physical contact through, for example, an IEEE 802.11 (Wi-Fi), Bluetooth, or a near-field communication (NFC) connection. Additionally, the I/O interface 336 may include a communications interface that allows communication between the detection system 330 and the remote station 340 using, for example, the Supervisory Control and Data Acquisition (SCADA) protocol or another services protocol. The remote station 340 may be any type of station through which an operator is able to communicate with the detection system 330 without making physical contact with the detection system 330. For example, the remote station 340 may be a computer-based work station, a smart phone, remote control, tablet, or a laptop computer that connects to the detection system 330 via a services protocol, or a remote control that connects to the detection system 330 via a radio-frequency signal.

The I/O interface 336 also may allow an external device or an operator to communicate with the detection system 330. The detection system 330 may be, for example, operated, configured, modified, or updated through the I/O interface 336. In addition to communications devices, the I/O interface 336 may include other I/O devices such as, for example, a display, audio input and/or output (such as speakers and/or a microphone), tactile interfaces (for example, buttons, sliders, and/or switches), and/or visual outputs (for example, an LED). Furthermore, the I/O interface 336 produces an interrupt 337 that is provided to the electronic processing module 332 and certain instructions may be executed in response to the interrupt 337. This allows manual operation of the monitoring apparatus 320. The interrupt 337 may be produced in ways other than direct interaction with the I/O interface 336. For example, the interrupt 337 may be produced periodically based on a timer that is implemented with executable instructions stored on the electronic storage 334.

FIGS. 6A and 6B are block diagrams of another monitoring apparatus 620. The monitoring apparatus 620 is another example of the monitoring apparatus 120. FIGS. 6A and 6B show the monitoring apparatus 620 attached to the exterior 111 of the protection device 110. The monitoring apparatus 620 includes a sensor 624 and the detection system 330. The monitoring apparatus 620 also includes electrical connections 623a and 623b. The electrical connection 623a electrically connects the sensor 624 to the current path 112 at a point 625a and the electrical connection 623b electrically connects the sensor 624 to the current path 112 at a point 625b. The points 625a and 625b are on opposite sides of the protection device 110. Referring also to FIG. 6C, the sensor 624 includes a light-emitting diode 642, which emits light 644 when electrical current flows in the diode 642, and an optical detector 643, which detects the light 644 and produces an output 626.

The current path 112 is closed in FIG. 6A. When the current path 112 is closed, electrical current can flow through the protection device 110 and the points 625a and 625b are at the same potential. Current does not flow through the light-emitting diode 642 if the voltage across the diode 642 is below the threshold voltage of the diode 642. The voltage across the diode 642 is the voltage difference between the points 625a and 625b. Thus, when there is no voltage difference between the points 625a and 625b, the light-emitting diode 642 does not conduct current and does not emit the light 644.

The current path 112 is opened in FIG. 6B. When the current path 112 is opened, electrical current cannot flow through the protection device 110 and the points 625a, 625b are not at the same potential. The light-emitting diode 642 conducts current and emits the light 644 when the potential difference across the light-emitting diode 642 exceeds the threshold voltage of the light-emitting diode 642. Thus, when the current path 122 is opened, the optical detector 643 detects the light 644 and provides the output 626 to the detection system 330.

FIGS. 7A and 7B are block diagrams of another monitoring apparatus 720. The monitoring apparatus 720 is another example of the monitoring apparatus 120. FIGS. 7A and 7B show the monitoring apparatus 720 attached to the exterior 111 of the protection device 110. The monitoring apparatus 720 includes the sensor 624, the detection system 330, a modulation system 751, and a demodulation system 752. The monitoring apparatus 720 also includes electrical connections 723a and 723b. The electrical connection 723a electrically connects the sensor 624 to the current path 112 at a point 725a and the electrical connection 723b electrically connects the sensor 624 to the current path 112 at a point 725b. The points 725a and 725b are on opposite sides of the monitoring apparatus 720.

In some implementations, the monitoring apparatus 720 also includes a switch between the sensor 624 and the point 725b. This switch is used to disconnect an optocoupler-based detection circuit to the current path 112 while high-frequency modulation current based detection is in progress. The optocoupler-based detection circuit includes a diode that may conduct current during this high-frequency modulation current detection and can provide false positive. The switch aids in reducing false positives in this configuration.

The current path 112 is closed in FIG. 7A. As discussed above, when the current path 112 is closed, electrical current can flow through the protection device 110, the points 725a and 725b are at the same potential, and the diode 642 does not emit the light 644. The modulation system 751 modulates the current in the current path 112 at the point 725a with a high-frequency signal 764. The high-frequency signal 764 is based on the unique identifier 339 of the detection system 330. The demodulation system 752 detects the high frequency signal 764 at the point 752b and demodulates the signal 764 to detect the unique identifier 339. The detected unique identifier 339 may be compared with the unique identifier 339 stored in the electronic storage 334 of the detection system to confirm that the demodulated current is current from the point 725b.

The current path 112 is opened in FIG. 7B. When the current path 112 is opened, electrical current cannot flow through the protection device 110 and the points 725a, 725b are not at the same potential. The light 644 is emitted by the light-emitting diode 642. Additionally, because no current flows through the protection device 110, there is no high-frequency modulation current at the point 725b for the demodulation system 752 to detect. The detection system 330 produces the fault indication 331. The fault indication 331 may include a representation of the unique identifier 339.

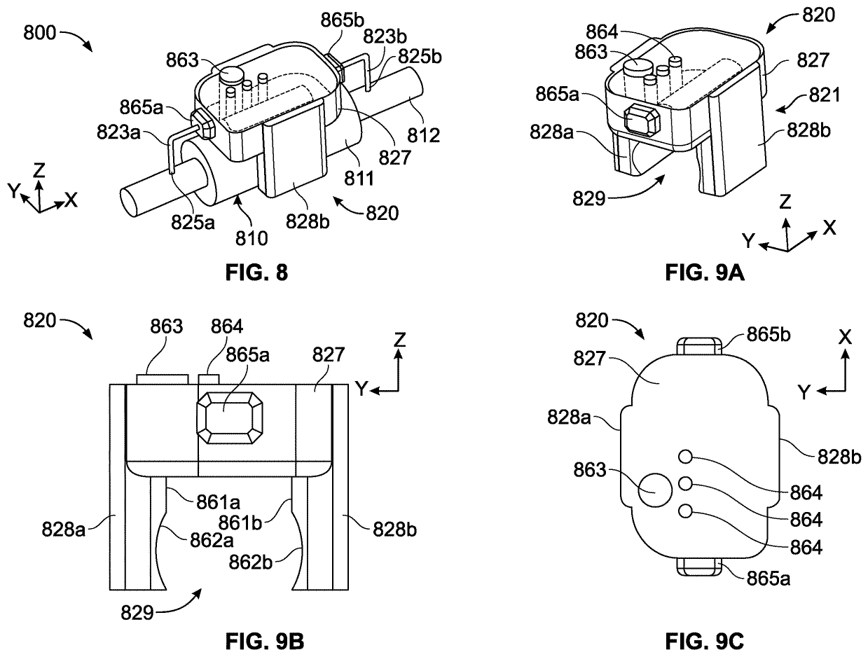

FIG. 8 is a perspective exterior view of a system 800 that includes a monitoring apparatus 820 mounted to an exterior 811 of a protection device 810. The monitoring apparatus 820 includes internal components similar to those of the monitoring apparatuses 120, 320, 420, 620, and/or 720 discussed above. For example, the monitoring apparatus 820 includes an electrical sensor (such as a light-emitting diode or a current sensor) and the detection system 330. The monitoring apparatus 820 includes electrical connections 823a, 823b that extend through respective electrical cable interfaces 865a, 865b. The electrical connections 823a, 823b are electrically connected to a conductor 812 at respective points 825a, 825b. The conductor 812 passes through the protection device 810. The protection device 810 includes a fuse or other opening element that opens the conductor 812 in the presence of a fault condition.

Referring also to FIG. 9A, which is a perspective view of the monitoring apparatus 820, and FIG. 9B, which is an end view of the monitoring apparatus 820, the monitoring apparatus 820 includes a body 821 with a top portion 827 and flexible grip elements 828a, 828b that extend in the-Z direction from opposite sides of the top portion 827. The body 821 may be made of, for example, a high-temperature grade thermoplastic such as polybutylene terephthalate (PY) and the flexible grip elements 828a, 828b may be made of a silicone-based material. Each flexible grip element 828a, 828b has a respective inner side 861a, 861b that includes a respective profile portion 862a, 862b. The profile portions 862a, 862b face each other and define a receiving region 829. The receiving region 829 is has a shape that at least partially matches the shape of the exterior 811 in the Y-Z plane. In the example shown in FIGS. 9A and 9B, the profile portions 862a, 862b are curved.

To attach the monitoring apparatus 820 to the protection device 810, the monitoring apparatus 820 is positioned over the protection device 810 with the receiving region 829 oriented toward the protection device 810. The monitoring apparatus 820 is pressed onto the exterior 811 and the flexible grip elements 828a, 828b deflect outward to increase the space between the inner sides 861a, 861b. The exterior 811 is received in the receiving region 829 and the flexible grip elements 828a, 828b move back toward each other to secure the profile portions 862a, 862b to the exterior 811 and attach the monitoring apparatus 820 to the protection device 810. The flexible nature of the flexible grip elements 828a, 828b allows the protection device 810 to be secured to a variety of protection devices having different sized and/or shaped exteriors. Additionally, the monitoring apparatus 820 is electrically connected to the conductor 812 with the electrical connections 823a, 823b.

Referring also to FIG. 9C, which is a top view of the monitoring apparatus 820, the monitoring apparatus 820 also includes a button 863 that extends in the Z direction from the top portion 827, lights 864 on the top portion 827, and an electrical cable connector interface 865 on a side of the top portion 827. The button 863 allows an operator to manually operate the monitoring apparatus 820. For example, pressing the button 863 may produce the interrupt 337 to turn on the monitoring apparatus 820, turn off the monitoring apparatus 820, and/or transition the monitoring apparatus 820 from a sleep state to an active state. In other example, pressing the button 863 can produce the interrupt 337 to manually reset the monitoring apparatus 820 after a fault condition. In another example, pressing the button 863 can produce the interrupt 337 that triggers a status check to determine whether the conductor 812 is opened. Furthermore, in some implementations, pressing button 863 in a particular manner (for example, two taps in rapid succession) may trigger a specific action in the monitoring apparatus 820. The lights 864 provide visual indications of various statuses. For example, the lights 864 may emit light when the protection device 810 detects a fault condition, when a power source in the monitoring apparatus 820 is low, and/or when the monitoring apparatus 820 is degraded or in need of repair.

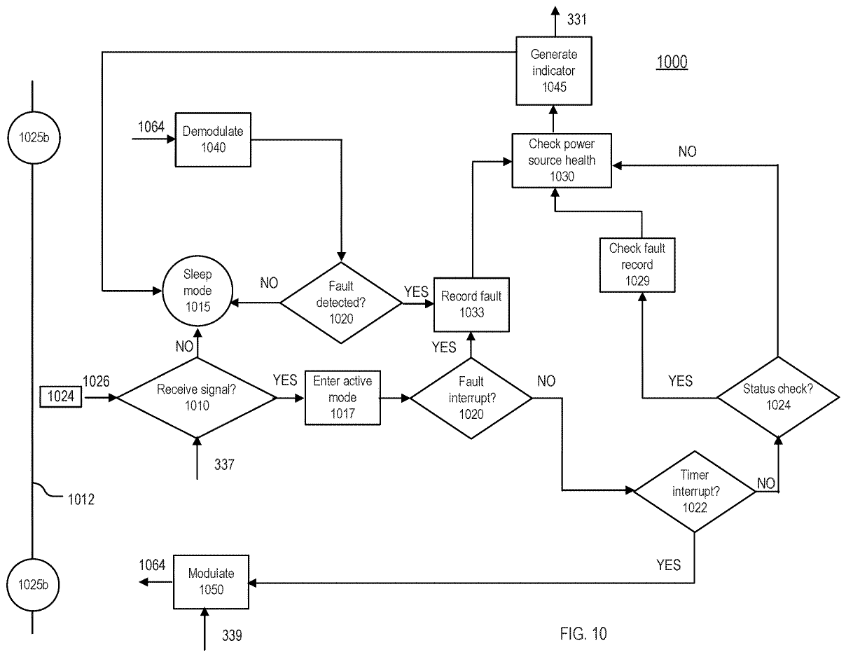

FIG. 10 is a flow chart of a process 1000. The process 1000 is an example of a process for producing the fault indication 331 with a monitoring apparatus (such as any of the monitoring apparatuses 120, 320, 420, 620, 720, 820) that is attached to a protection device such as a cable limiter that includes a conductor 1012. The process 1000 may be implemented as executable instructions stored on the electronic storage 334 and performed by the electronic processing module 332 of the detection system 330. In the discussion below, the detection system 330 is typically in a sleep mode to conserve energy. However, in some implementations, the detection system 330 is typically in an active mode.

Whether an output 1026 and/or an interrupt 337 is received is determined (1010). The output 1026 is generated by a sensor 1024 that monitors current flow in the conductor 1012 in the protection device. The sensor 1024 may include a light-emitting diode and an optical detector, such as discussed with respect to the sensor 624. The output 1026 is a measurement or representation of voltage on the conductor 1012 and/or current in the conductor 1012. In the presence of a fault condition, the protection device opens the conductor 1012, current does not flow in the conductor 1012, and the voltage between two points 1025a, 1025b on the conductor 1012 is non-zero. Examples of conditions that can cause a fault condition include, without limitation, an earth short circuit, a phase short circuit, an upstream and/or downstream breaker open condition and/or fault condition, an asynchronous pulse short circuit fault, and a continuous overcurrent.

The interrupt 337 may be generated in response to operator input or by an process executed by the detection system 330. For example, the interrupt 337 may be generated when a manual interface (such as the button 863) is pressed. Furthermore, the interrupt 337 may include information about actions to be taken in response to the interrupt 337. For example, the manual interface may be configured for several different modes of manipulation and each mode of manipulation has an associated flag, value, or other information that is included in the interrupt 337. Furthermore, the interrupt 337 may be generated by an internal process in the detection system 330. For example, the interrupt 337 may be a time-based interrupt that is generated periodically to check the status of the protection device.

If the output 1026 and/or the interrupt 337 are received, the detection system 330 is placed in the active mode (1017). To enter the active mode, the detection system 330 may turn on the power source 338 and/or electrically connect to the power source 338. If the output 1026 or an interrupt 337 are not received, the detection system 330 remains in the sleep mode (1015).

The signal received at (1010) is analyzed to determine if there is a fault interrupt (1020). For example, if the signal is the output 1026, the voltage and/or current measurement in the output 1026 is compared to a threshold or a criterion to determine whether the output 1026 indicates that there is a fault in the protection device. If the measurement is indicative of a fault condition, the output 1026 is determined to be a fault interrupt. In another example, the signal is the interrupt 337, which may be a status inquiry, a timer interrupt, or a manual indication of a fault condition. The status inquiry and the timer interrupt are examples of signals that are not fault interrupts.

If the signal received at (1010) is a fault interrupt, the fault is recorded (1033). For example, the occurrence of the fault may be stored in the fault record 333 on the electronic storage 334 in association with information about the fault. Examples of the information include the time of the fault and/or measurement(s) associated with the fault. If the signal received at (1010) is not a fault interrupt, the signal is analyzed to determine if the signal is a timer interrupt (1022). If the fault interrupt is a timer interrupt, current that flows in the conductor 1012 is modulated into a modulated current 1064 based on the unique identifier 339 (1050). The modulated current 1064 is provided to the point 1025a on the conductor 1012. The modulated current 1064 is sampled from the point 1025b (which is on the other side of the protection device as compared to the point 1025a) and is demodulated (1040). Based on output of (1040), it is determined whether or not a fault is detected (1020). As discussed above, when there is a fault in the protection device, current does not flow in the conductor 1012. Thus, if the modulated current 1064 is demodulated, no fault is detected and the detection system 330 is placed in the sleep mode (1015).

If the there is no modulated current 1064 at the point 1025b, a fault condition is detected. The detected fault is added to the fault record 333 (1033). The health of the power source is assessed (1030). The fault indication 331 is generated (1045). The fault indication 331 is provided to the remote device 340. For example, a cellular modem or Wi-Fi transmitter in the detection system 330 is controlled to transmit the fault indication 331 to the remote device 340. The fault indication 331 also may include information related to the detected fault, information about the health of the power source 338, and information that represents the unique identifier 339 of the detection system 330. After every fault indication 331, the detection system goes back to sleep mode (1015) after predefined timeout.

Furthermore, if the signal is determined to not be a timer interrupt (1024) and the signal is not a status check interrupt, the health of the power source 338 is checked (1030), and the fault indication 331 is produced (1045). When the fault indication 331 is produced through this path, a fault condition has not necessarily been detected. Thus, the fault indication 331 includes information about the health of the power source 338 but does not necessarily include information about a fault condition.

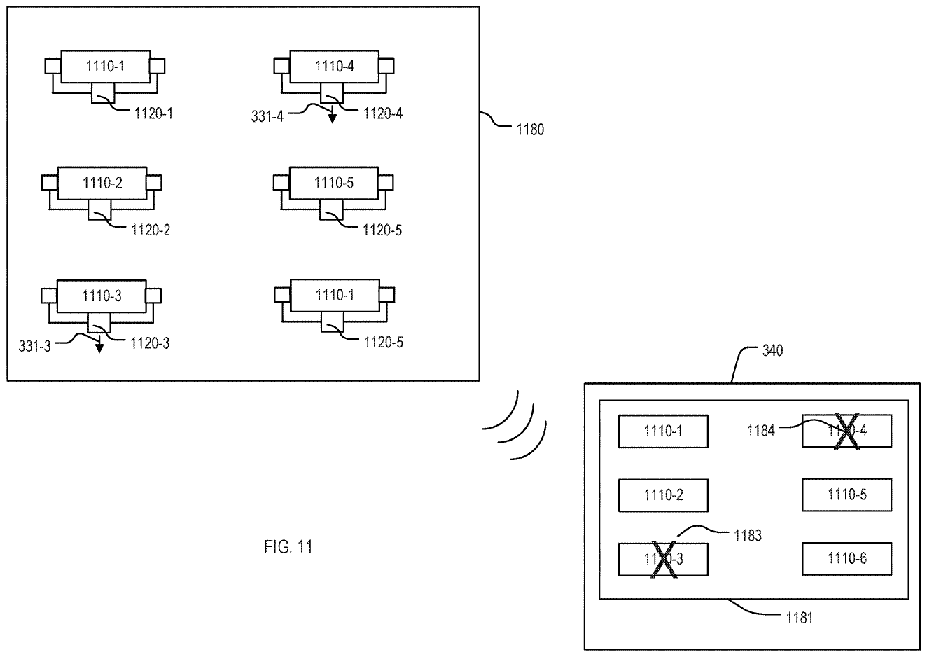

FIG. 11 shows a system 1100 that includes a fleet 1180 and the remote station 340. The fleet 1180 includes monitoring apparatuses 1120-1, 1120-2, 1120-3, 1120-4, 1120-5, 1120-6 mounted to respective protective devices 1110-1, 1110-2, 1110-3, 1110-4, 1110-5, 1110-6. Each monitoring apparatus 1120-1, 1120-2, 1120-3, 1120-4, 1120-5, 1120-6 includes an instance of the detection system 330 that communicates with the remote station 340.

The remote station 340 presents a status map 1181. The status map 1181 may be presented as, for example, a web-based visual interface or a visualization in an app on a smart phone or tablet. The status map 1181 presents an electronic representation of each monitoring apparatus 1120-1, 1120-2, 1120-3, 1120-4, 1120-5, 1120-6. Each electronic representation includes a label to associate the representation with a corresponding one of the monitoring apparatus 1120-1, 1120-2, 1120-3, 1120-4, 1120-5, 1120-6. Additionally, in the example shown, the electronic representations are spatially arranged in a manner similar to how the monitoring apparatuses 1120-1, 1120-2, 1120-3, 1120-4, 1120-5, 1120-6 are spatially arranged on-site within the fleet 1180.

In the example shown, the protection devices 1110-3 and 1110-4 have a fault condition and the monitoring apparatuses 1120-3 and 1120-4 produce fault indications 331-3 and 331-4. The status map 1181 displays visual fault indicators 1183 and 1184 on the electronic representations of the protection devices 1110-3 and 1110-4 (respectively) to show that the protection devices 1110-3 and 1110-4 have fault conditions. The remaining protection devices 1110-1, 1110-2, 1110-5, and 1110-6 do not have visual fault indicators. Thus, the status map 1181 allows rapid determination of the status of individual protection devices in the fleet 1180.

These and other implementations are within the scope of the claims.

What is claimed is:

1. A monitoring apparatus comprising:
a base configured to attach to an exterior of a cable protection device, the cable protection device comprising a current path that opens in response to an electrical fault; and
a fault detection system in the base, the fault detection system comprising: a fault indication module configured to produce a fault indication when the current path is open, wherein the base is configured to fit over at least a portion of the exterior of any one of a plurality of cable protection devices, and at least two of the plurality of cable protection devices have different characteristics.

2. The monitoring apparatus of claim 1, wherein the fault detection system further comprises:
an electrical sensor configured to measure one or more properties of electricity in the current path and to produce an output based on the one or more properties of electricity in the current path, and the fault indication module is configured to produce the fault indication when the output indicates that the current path is open.

3. The monitoring apparatus of claim 2, wherein the monitoring apparatus further comprises:
a first electrical connection configured to electrically connect to the current path;
a second electrical connection configured to electrically connect to the current path; and
the electrical sensor comprises a voltage sensor electrically connected to the first electrical connection and the second electrical connection, the voltage sensor configured to measure a potential difference between the first and second electrical connections and to produce an output that represents the potential difference; and
the fault detection system is configured to produce the fault indication when there is a non-zero potential difference.

4. The monitoring apparatus of claim 3, wherein the voltage sensor comprises an optical sensor that emits light when there is a non-zero potential difference; and
the fault detection system further comprises:
a detector configured to detect light and produce an electrical signal based on detected light; and
an electronic control system configured to produce the fault indication based on the electrical signal.

5. The monitoring apparatus of claim 4, wherein the monitoring apparatus further comprises:
a modulation module electrically connected to the electronic control system and the current path; and
a demodulation module electrically connected to the electronic control system and the current path.

6. The monitoring apparatus of claim 5, wherein the modulation module is configured to modulate electrical current in the current path to produce modulated electrical current based on a unique identifier associated with the electronic control system; and the demodulation module is configured to demodulate the modulated electrical current.

7. The monitoring apparatus of claim 2, wherein the fault detection system comprises:
a current sensor configured to sense current in the current path and to produce a measurement of an amount of current in the current path; and wherein the fault detection system is configured to produce the fault indication when the measurement indicates that the amount of current flowing in the current path is below a threshold.

8. The monitoring apparatus of claim 1, wherein the fault detection system comprises:
an electronic control system;
a modulation module electrically connected to the current path and the electronic control system; and
a demodulation module electrically connected to the current path and the electronic control system, and wherein the modulation module is configured to modulate electrical current on the current path based on a unique identifier associated with the electronic control system to produce a modulated signal; and the demodulation module is configured to demodulate the modulated signal to produce a demodulated signal; and
wherein the electronic control system produces the fault indication when the demodulated signal is not received at the electronic control system.

9. The monitoring apparatus of claim 1, further comprising a communications device configured to provide the fault indication to a separate device.

10. The monitoring apparatus of claim 9, wherein the communications device comprises a wireless communication device.

11. The monitoring apparatus of claim 1, wherein the base comprises a flexible attachment device that extends from the base and fits over at least a portion of the exterior of the cable protection device to attach the base to the exterior of the cable protection device.

12. The monitoring apparatus of claim 1, wherein the characteristics comprise one or more of an outer diameter, a cable size, a length, a terminal type, and an electrical rating.

13. The monitoring apparatus of claim 1, wherein the characteristics comprise a spatial feature of an exterior of the cable protection device.

14. A cable protection monitoring system configured to:
present a visual representation of a fleet of fault detection apparatuses, wherein each of the fault detection apparatuses is attached to a respective one of a plurality of cable protection devices, and each of the fault detection apparatuses is configured to produce a fault indication signal in response to detecting a fault in its respective attached cable protection device;
receive a fault indication signal for one or more of the fault detection apparatuses; and
display a fault symbol in association with the one or more of the fault detection apparatuses in the visual representation of the fleet.

15. The cable protection monitoring system of claim 14, wherein each fault detection apparatus is associated with a unique identifier, and the fault indication signal produced by each fault detection apparatus comprises a representation of the unique identifier.

16. The cable protection monitoring system of claim 14, further comprising the fleet of fault detection apparatuses.

17. A system comprising:
a base configured for mounting to an exterior of a cable protection device;
a fault detection system in the base, the fault detection system comprising:
a sensor configured to detect a fault in the cable protection device and to present a visible indication of a detected fault in the cable protection device; and
an interface configured to trigger a status check to determine whether a fault is present in the cable protection device.

18. The system of claim 17, wherein the sensor comprises an optical sensor electrically connected to two points along a current path in the cable protection device, and the optical sensor is configured to emit light in response to a non-zero potential difference between the two points.
